(19) United States
(12) Patent Application Publication
(10) Pub. No.: US 2025/0301914 A1
(43) Pub. Date: Sep. 25, 2025

(54) MAGNETIC MEMORY DEVICE

(71) Applicant: Kioxia Corporation, Tokyo (JP)

(72) Inventors: Kazuya SAWADA, Seoul (KR); Tadaaki OIKAWA, Seoul (KR); Soichi OIKAWA, Seoul (KR); Kenji FUKUDA, Seoul (KR)

(73) Assignee: Kioxia Corporation, Tokyo (JP)

(21) Appl. No.: 19/079,213

(22) Filed: Mar. 13, 2025

(30) Foreign Application Priority Data
Mar. 19, 2024 (JP) 2024-043747

(51) Int. Cl. H10N 50/10; G11C 11/16; H10N 50/85

(52) U.S. Cl. CPC H10N 50/10; G11C 11/161; H10N 50/85

(57) ABSTRACT

According to one embodiment, a magnetic memory device includes first, second and third magnetic layers having variable, fixed and fixed magnetization directions, respectively, a nonmagnetic layer, and a spacer layer. The second magnetic layer is between the first and third magnetic layers, the nonmagnetic layer is between the first and second magnetic layers, the spacer layer is between the second and third magnetic layers, the second magnetic layer includes a layer adjacent to the spacer layer and including a first layer portion formed of Co and a second layer portion containing N, the third magnetic layer includes a layer adjacent to the spacer layer and including a first layer portion formed of Co.

### CROSS-REFERENCE TO RELATED APPLICATIONS

This application is based upon and claims the benefit of priority from Japanese Patent Application No. 2024-043747, filed Mar. 19, 2024, the entire contents of which are incorporated herein by reference.

### FIELD

Embodiments described herein relate generally to a magnetic memory device.

### BACKGROUND

A magnetic memory device with a plurality of magnetoresistance effect elements integrated on a semiconductor substrate has been proposed.

### BRIEF DESCRIPTION OF THE DRAWINGS

FIG. 1 is a cross-sectional view schematically showing a basic configuration of a magnetic memory device of a first embodiment.

FIG. 2 is a cross-sectional view schematically showing the basic configuration of the magnetic memory device of a modified example of the first embodiment.

FIG. 3 is a cross-sectional view schematically showing a basic configuration of a magnetic memory device of a second embodiment.

FIG. 4 is a cross-sectional view schematically showing the basic configuration of the magnetic memory device of a modified example of the second embodiment.

FIG. 5 is a cross-sectional view schematically showing a basic configuration of a magnetic memory device of a third embodiment.

### DETAILED DESCRIPTION

In general, according to one embodiment, a magnetic memory device includes: a first magnetic layer having a variable magnetization direction; a second magnetic layer having a fixed magnetization direction; a third magnetic layer having a fixed magnetization direction which is antiparallel to the magnetization direction of the second magnetic layer; a nonmagnetic layer; and a spacer layer, wherein the second magnetic layer is provided between the first magnetic layer and the third magnetic layer, the nonmagnetic layer is provided between the first magnetic layer and the second magnetic layer, the spacer layer is provided between the second magnetic layer and the third magnetic layer, the second magnetic layer includes a first adjacent layer which is adjacent to the spacer layer, the third magnetic layer includes a second adjacent layer which is adjacent to the spacer layer, the first adjacent layer includes a first layer portion substantially formed of cobalt (Co) and a second layer portion containing nitrogen (N), the first layer portion is provided between the spacer layer and the second layer portion and is in contact with the spacer layer and the second layer portion, and the second adjacent layer includes a first layer portion which is substantially formed of cobalt (Co) and is in contact with the spacer layer.

Embodiments will be described hereinafter with reference to the accompanying drawings.

### First Embodiment

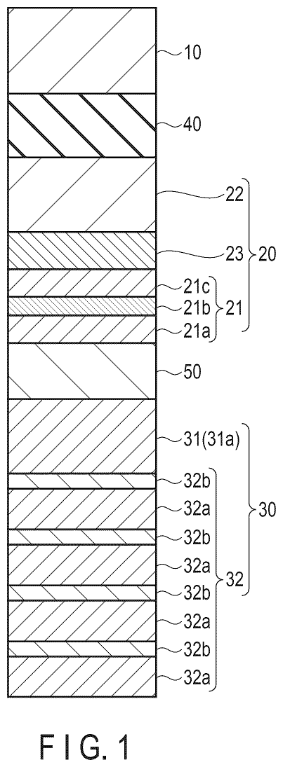

FIG. 1 is a cross-sectional view schematically showing a basic configuration of a magnetic memory device of a first embodiment. More specifically, FIG. 1 is a cross-sectional view schematically showing the basic configuration of a magnetoresistance effect element included in the magnetic memory device. The magnetoresistance effect element is a magnetic tunnel junction (MTJ) element having perpendicular magnetization.

The magnetoresistance effect element shown in FIG. 1 comprises a storage layer (first magnetic layer) 10, a reference layer (second magnetic layer) 20, a shift canceling layer (third magnetic layer) 30, a tunnel barrier layer (nonmagnetic layer) 40, and a spacer layer 50, and these layers 10 to 50 have a stacked structure.

More specifically, the reference layer 20 is provided between the storage layer 10 and the shift canceling layer 30, a tunnel barrier layer 40 is provided between the storage layer 10 and the reference layer 20, and the spacer layer 50 is provided between the reference layer 20 and the shift canceling layer 30.

The storage layer 10 is a ferromagnetic layer having a variable magnetization direction. Incidentally, the variable magnetization direction indicates that the magnetization direction changes with respect to a predetermined write current. The storage layer 10 contains at least iron (Fe). More specifically, the storage layer 10 is formed of an FeCoB layer containing iron (Fe), cobalt (Co), and boron (B).

The reference layer 20 is a ferromagnetic layer having a fixed magnetization direction. Incidentally, the fixed magnetization direction indicates that the magnetization direction does not change with respect to a predetermined write current. The reference layer 20 includes an adjacent layer (first adjacent layer) 21 that is adjacent to the spacer layer 50, an interface layer 22, and an intermediate layer 23.

The adjacent layer 21 includes a cobalt layer (first layer portion) 21a substantially formed of cobalt (Co), a nitrogen-containing layer (second layer portion) 21b containing nitrogen (N), and a cobalt layer (third layer portion) 21c substantially formed of cobalt (Co).

More specifically, the cobalt layer 21a is provided between the spacer layer 50 and the nitrogen-containing layer 21b and is in contact with the spacer layer 50 and the nitrogen-containing layer 21b. The nitrogen-containing layer 21b is provided between the cobalt layer 21a and the cobalt layer 21c and is in contact with the cobalt layer 21a and the cobalt layer 21c.

As described above, the cobalt layers 21a and 21c are substantially formed of cobalt (Co). In other words, ideally, the cobalt layers 21a and 21c are desirably formed of cobalt only without containing any unintended elements other than cobalt. However, in practice, the layers may contain trace amounts of unintended elements other than cobalt. Therefore, being substantially formed of cobalt also implies a case where the cobalt layer contains not only cobalt, but also trace amounts of unintended elements other than cobalt, as well as a case where the cobalt layer is formed of cobalt only. Incidentally, in the following descriptions as well, the meaning of “being substantially formed” is the same as the above-described meaning, and implies a case where trace amounts of unintended elements are contained.

The nitrogen-containing layer 21b contains predetermined elements in addition to nitrogen (N) and is substantially formed of nitrogen and the predetermined element. In other words, ideally, the nitrogen-containing layer 21b is desirably formed of only nitrogen and the predetermined element. However, the layer may contain not only nitrogen and predetermined element, but also trace amounts of unintended elements other than nitrogen and the predetermined element. In the embodiment, the nitrogen-containing layer 21b contains cobalt (Co) as the predetermined element in addition to nitrogen (N). The nitrogen-containing layer 21b is basically a nitrogen compound and, in the embodiment, the nitrogen-containing layer 21b is formed of cobalt nitride (CON).

The reference layer 20 includes an additional layer in addition to the adjacent layer 21. The additional layer includes the interface layer 22 and the intermediate layer 23 and is provided between the tunnel barrier layer 40 and the adjacent layer 21.

The interface layer 22 contains at least iron (Fe) and is specifically formed of an FeCoB layer containing iron (Fe), cobalt (Co), and boron (B).

The intermediate layer 23 is formed of a layer containing molybdenum (Mo), tantalum (Ta), or tungsten (W) and is provided between the adjacent layer 21 and the interface layer 22.

The shift canceling layer 30 is a ferromagnetic layer having a fixed magnetization direction which is antiparallel to the magnetization direction of the reference layer 20, and comprises a function of canceling the magnetic stray field applied from the reference layer 20 to the storage layer 10. The shift canceling layer 30 includes an adjacent layer (second adjacent layer) 31 that is adjacent to the spacer layer 50, and a superlattice layer 32. The adjacent layer 31 is provided between the spacer layer 50 and the superlattice layer 32.

The adjacent layer 31 includes a cobalt layer (first layer portion) 31a that is substantially formed of cobalt (Co) and is in contact with the spacer layer 50. In other words, the cobalt layer 31a is ideally formed of cobalt only, but may also contain trace amounts of unintended elements other than cobalt in addition to cobalt. In the embodiment, the adjacent layer 31 is formed of only the cobalt layer 31a.

The superlattice layer 32 has a superlattice structure in which a plurality of cobalt layers 32a each substantially formed of cobalt (Co) and a plurality of predetermined element layers 32b each substantially formed of a predetermined element are stacked alternately. The predetermined element is selected from platinum (Pt), nickel (Ni), and palladium (Pd). In the embodiment, platinum layers are used as the predetermined element layers 32b.

The tunnel barrier layer 40 is an insulating layer provided between the storage layer 10 and the reference layer 20. The tunnel barrier layer 40 is substantially formed of a MgO layer containing magnesium (Mg) and oxygen (O).

The spacer layer 50 is an electrically conductive layer provided between the reference layer 20 and the shift canceling layer 30, and exchange coupling (antiferromagnetic exchange coupling) is executed between the reference layer 20 and the shift canceling layer 30 via the spacer layer 50. More specifically, the spacer layer 50 is provided between the cobalt layer 21a and the cobalt layer 31a and is in contact with the cobalt layer 21a and the cobalt layer 31a. The spacer layer 50 is formed of an iridium layer, which is substantially formed of iridium (Ir), or a ruthenium layer, which is substantially formed of ruthenium (Ru).

In the above-described magnetoresistance effect element, when the magnetization direction of the storage layer 10 is parallel to the magnetization direction of the reference layer 20, the magnetoresistance effect element is in a low-resistance state with relatively low resistance. When the magnetization direction of the storage layer 10 is antiparallel to the magnetization direction of the reference layer 20, the magnetoresistance effect element is in a high-resistance state with relatively high resistance. Therefore, the above-described magnetoresistance effect element is capable of storing binary data in accordance with its resistance state.

In addition, the above-described magnetoresistance effect element is a spin transfer torque (STT) type magnetoresistance effect element and has perpendicular magnetization. In other words, the magnetization direction of the storage layer 10 is perpendicular to the main surface of the storage layer 10, the magnetization direction of the reference layer 20 is perpendicular to the main surface of the reference layer 20, and the magnetization direction of the shift canceling layer 30 is perpendicular to the main surface of the shift canceling layer 30.

As described above, in the embodiment, the nitrogen-containing layer 21b is provided in the adjacent layer 21 of the reference layer 20, and the cobalt layer 21a which is in contact with the spacer layer 50 is provided between the spacer layer 50 and the nitrogen-containing layer 21b. In the embodiment, with this configuration, a magnetic memory device capable of increasing the magnitude of the exchange coupling between the reference layer 20 and the shift canceling layer 30, and having excellent characteristics as described below can be obtained.

In the embodiment, the magnitude of the exchange coupling between the reference layer 20 and the shift canceling layer 30 can be increased by providing the above-described nitrogen-containing layer 21b. As a result, a magnetic memory device capable of reducing the write current Ic and having excellent characteristics such as high-speed writing, long life, and low power consumption can be obtained.

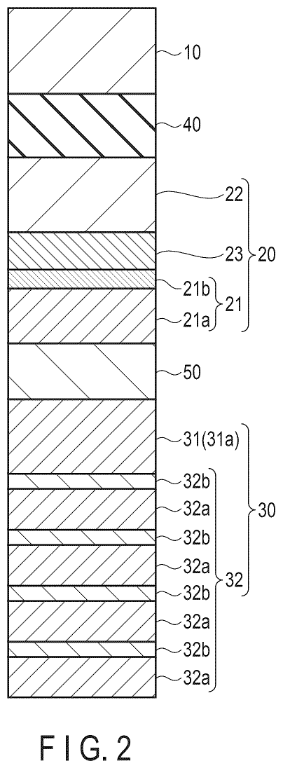

FIG. 2 is a cross-sectional view schematically showing the basic configuration of the magnetic memory device of a modified example of the first embodiment.

In the above-described embodiment, the nitrogen-containing layer 21b is provided between the cobalt layer 21a and the cobalt layer 21c. In a modified example, however, the cobalt layer 21c is not provided, and the nitrogen-containing layer 21b is provided between the cobalt layer 21a and an additional layer (interface layer 22 and intermediate layer 23). In other words, in the modified example, the nitrogen-containing layer 21b is in contact with the cobalt layer 21a and the additional layer (specifically, the intermediate layer 23 included in the additional layer).

In the modified example as well, similarly to the above-described embodiment, the nitrogen-containing layer 21b is provided in the adjacent layer 21 of the reference layer 20, and the cobalt layer 21a which is in contact with the spacer layer 50 is provided between the spacer layer 50 and the nitrogen-containing layer 21b. Therefore, in the modified example as well, similarly to the above-described embodiment, a magnetic memory device capable of increasing the magnitude of the exchange coupling between the reference layer 20 and the shift canceling layer 30, and having excellent characteristics can be obtained.

### Second Embodiment

Next, a second embodiment will be described. Incidentally, basic elements are the same as those of the first embodiment, and descriptions of the elements described in the first embodiment are omitted.

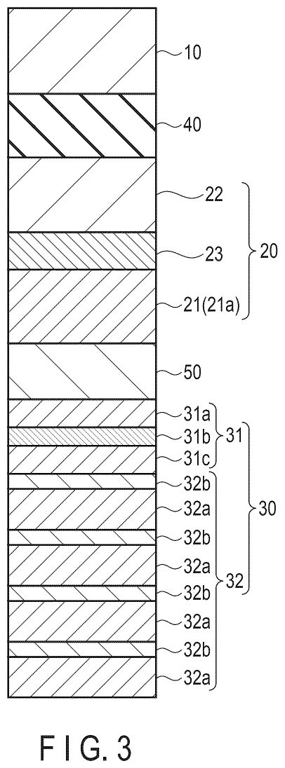

FIG. 3 is a cross-sectional view schematically showing a basic configuration of a magnetic memory device of a second embodiment.

In the embodiment as well, similarly to the first embodiment, an adjacent layer (first adjacent layer) 21 of a reference layer 20 includes a cobalt layer (first layer portion) 21a that is substantially formed of cobalt (Co) and is in contact with a spacer layer 50. In the embodiment, however, a nitrogen-containing layer 21b is not provided in the adjacent layer 21 of the reference layer 20, and the adjacent layer 21 is formed of the cobalt layer 21a only.

In the embodiment, an adjacent layer (second adjacent layer) 31 of a shift canceling layer 30 includes a cobalt layer (first layer portion) 31a substantially formed of cobalt (Co), a nitrogen-containing layer (second layer portion) 31b containing nitrogen (N), and a cobalt layer (third layer portion) 31c substantially formed of cobalt (Co).

More specifically, the cobalt layer 31a is provided between the spacer layer 50 and the nitrogen-containing layer 31b and is in contact with the spacer layer 50 and the nitrogen-containing layer 31b. The nitrogen-containing layer 31b is provided between the cobalt layer 31a and the cobalt layer 31c and is in contact with the cobalt layer 31a and the cobalt layer 31c. In other words, the adjacent layer 31 of the embodiment has the same configuration as that of the adjacent layer 21 of the first embodiment.

Similarly to the nitrogen-containing layer 21b of the first embodiment, the nitrogen-containing layer 31b of the embodiment also contains a predetermined element in addition to nitrogen (N), and is substantially formed of nitrogen and the predetermined element. More specifically, similarly to the nitrogen-containing layer 21b of the first embodiment, the nitrogen-containing layer 31b of the embodiment also contains cobalt (Co) as the predetermined element in addition to nitrogen (N), and is formed of cobalt nitride (CoN).

As described above, in the embodiment, the nitrogen-containing layer 31b is provided in the adjacent layer 31 of the shift canceling layer 30, and the cobalt layer 31a which is in contact with the spacer layer 50 is provided between the spacer layer 50 and the nitrogen-containing layer 31b. Therefore, in the embodiment as well, with the configuration, a magnetic memory device capable of increasing the magnitude of the exchange coupling between the reference layer 20 and the shift canceling layer 30, by the same effects as those of the first embodiment, and having excellent characteristics can be obtained.

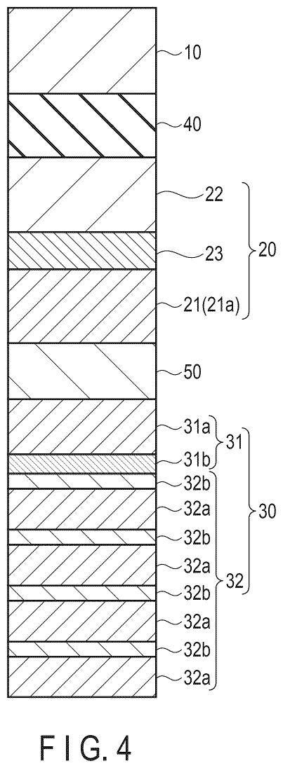

FIG. 4 is a cross-sectional view schematically showing the basic configuration of the magnetic memory device of a modified example of the second embodiment.

In the above-described embodiment, the nitrogen-containing layer 31b is provided between the cobalt layer 31a and the cobalt layer 31c. In the modified example, however, the cobalt layer 31c is not provided, and the nitrogen-containing layer 31b is provided between the cobalt layer 31a and a superlattice layer 32. In other words, in the modified example, the nitrogen-containing layer 31b is in contact with the cobalt layer 31a and the superlattice layer 32.

In the modified example as well, similarly to the above-described embodiment, the nitrogen-containing layer 31b is provided in the adjacent layer 31 of the shift canceling layer 30, and the cobalt layer 31a which is in contact with the spacer layer 50 is provided between the spacer layer 50 and the nitrogen-containing layer 31b. Therefore, in the modified example as well, similarly to the above-described embodiment, a magnetic memory device capable of increasing the magnitude of the exchange coupling between the reference layer 20 and the shift canceling layer 30, and having excellent characteristics can be obtained.

### Third Embodiment

Next, a third embodiment will be described. Incidentally, basic elements are the same as those of the first and second embodiments, and descriptions of the elements described in the first and second embodiments are omitted.

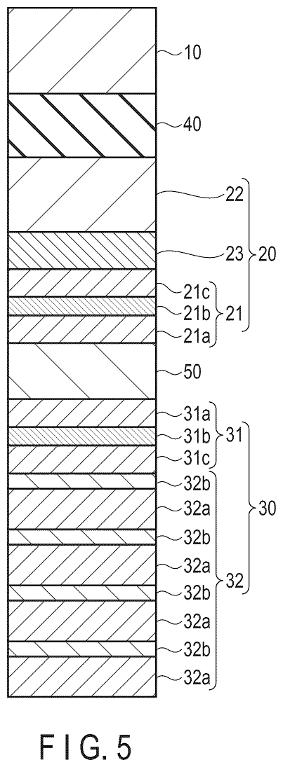

FIG. 5 is a cross-sectional view schematically showing a basic configuration of a magnetic memory device of a third embodiment.

In the embodiment, the adjacent layer 21 of the reference layer 20 has the same configuration as that in the first embodiment, and the adjacent layer 31 of the shift canceling layer 30 has the same configuration as that in the second embodiment.

Therefore, in the embodiment as well, similarly to the first and second embodiments, a magnetic memory device capable of increasing the magnitude of the exchange coupling between the reference layer 20 and the shift canceling layer 30, and having excellent characteristics can be obtained.

Incidentally, as a modified example of the embodiment, the configuration of the adjacent layer 21 of the reference layer 20 may be made the same as the configuration of the first embodiment shown in FIG. 1, and the configuration of the adjacent layer 31 of the shift-canceling layer 30 may be made the same as the configuration of the modified example of the second embodiment shown in FIG. 4. In addition, the configuration of the adjacent layer 21 of the reference layer 20 may be made the same as the configuration of the modified example of the first embodiment shown in FIG. 2, and the configuration of the adjacent layer 31 of the shift-canceling layer 30 may be made the same as the configuration of the second embodiment shown in FIG. 3. In addition, the configuration of the adjacent layer 21 of the reference layer 20 may be made the same as the configuration of the modified example of the first embodiment shown in FIG. 2, and the configuration of the adjacent layer 31 of the shift-canceling layer 30 may be made the same as the configuration of the modified example of the second embodiment shown in FIG. 4.

Incidentally, in the above-described first, second, and third embodiments, a top-free magnetoresistance effect element in which the storage layer 10 is located on the upper side of the reference layer 20 has been described. However, a bottom-free magnetoresistance effect element in which the storage layer 10 is located on the lower side of the reference layer 20 may be used. In this case, in each of the configurations shown in FIG. 1 to FIG. 5, the order of stacking the layers that constitute the magnetoresistance effect element is reversed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
a first magnetic layer having a variable magnetization direction;
a second magnetic layer having a fixed magnetization direction;
a third magnetic layer having a fixed magnetization direction which is antiparallel to the magnetization direction of the second magnetic layer;
a nonmagnetic layer; and
a spacer layer,
wherein
the second magnetic layer is provided between the first magnetic layer and the third magnetic layer,
the nonmagnetic layer is provided between the first magnetic layer and the second magnetic layer,
the spacer layer is provided between the second magnetic layer and the third magnetic layer,
the second magnetic layer includes a first adjacent layer which is adjacent to the spacer layer,
the third magnetic layer includes a second adjacent layer which is adjacent to the spacer layer,
the first adjacent layer includes a first layer portion substantially formed of cobalt (Co) and a second layer portion containing nitrogen (N),
the first layer portion is provided between the spacer layer and the second layer portion and is in contact with the spacer layer and the second layer portion, and
the second adjacent layer includes a first layer portion which is substantially formed of cobalt (Co) and is in contact with the spacer layer.

2. The device of claim 1, wherein
the second layer portion of the first adjacent layer further contains cobalt (Co).

3. The device of claim 1, wherein
the first adjacent layer further includes a third layer portion substantially formed of cobalt (Co), and
the second layer portion of the first adjacent layer is provided between the first layer portion of the first adjacent layer and the third layer portion of the first adjacent layer and is in contact with the third layer portion of the first adjacent layer.

4. The device of claim 1, wherein
the second adjacent layer further includes a second layer portion containing nitrogen (N), and
the first layer portion of the second adjacent layer is provided between the spacer layer and the second layer portion of the second adjacent layer and is in contact with the second layer portion of the second adjacent layer.

5. The device of claim 1, wherein
the second magnetic layer further includes an additional layer provided between the nonmagnetic layer and the first adjacent layer.

6. The device of claim 5, wherein
the additional layer includes a layer containing iron (Fe).

7. The device of claim 6, wherein
the additional layer further includes a layer containing molybdenum (Mo), tantalum (Ta), or tungsten (W) and provided between the first adjacent layer and the layer containing iron.

8. The device of claim 1, wherein
the third magnetic layer further includes a superlattice layer in which a plurality of cobalt layers each substantially formed of cobalt (Co) and a plurality of predetermined element layers each substantially formed of a predetermined element are stacked alternately,
the predetermined element is selected from platinum (Pt), nickel (Ni), and palladium (Pd), and
the second adjacent layer is provided between the spacer layer and the superlattice layer.

9. A magnetic memory device comprising:
a first magnetic layer having a variable magnetization direction;
a second magnetic layer having a fixed magnetization direction;
a third magnetic layer having a fixed magnetization direction which is antiparallel to the magnetization direction of the second magnetic layer;
a nonmagnetic layer; and
a spacer layer,
wherein
the second magnetic layer is provided between the first magnetic layer and the third magnetic layer,
the nonmagnetic layer is provided between the first magnetic layer and the second magnetic layer,
the spacer layer is provided between the second magnetic layer and the third magnetic layer,
the second magnetic layer includes a first adjacent layer which is adjacent to the spacer layer,
the third magnetic layer includes a second adjacent layer which is adjacent to the spacer layer,
the second adjacent layer includes a first layer portion substantially formed of cobalt (Co) and a second layer portion containing nitrogen (N),
the first layer portion is provided between the spacer layer and the second layer portion and is in contact with the spacer layer and the second layer portion, and
the first adjacent layer includes a first layer portion which is substantially formed of cobalt (Co) and is in contact with the spacer layer.

10. The device of claim 9, wherein
the second layer portion of the second adjacent layer further contains cobalt (Co).

11. The device of claim 9, wherein
the second adjacent layer further includes a third layer portion substantially formed of cobalt (Co), and
the second layer portion of the second adjacent layer is provided between the first layer portion of the second adjacent layer and the third layer portion of the second adjacent layer and is in contact with the third layer portion of the second adjacent layer.

12. The device of claim 9, wherein
the second magnetic layer further includes an additional layer provided between the nonmagnetic layer and the first adjacent layer.

13. The device of claim 12, wherein
the additional layer includes a layer containing iron (Fe).

14. The device of claim 13, wherein
the additional layer further includes a layer containing molybdenum (Mo), tantalum (Ta), or tungsten (W) and provided between the first adjacent layer and the layer containing iron.

15. The device of claim 9, wherein
the third magnetic layer further includes a superlattice layer in which a plurality of cobalt layers each substantially formed of cobalt (Co) and a plurality of predetermined element layers each substantially formed of a predetermined element are stacked alternately,
the predetermined element is selected from platinum (Pt), nickel (Ni), and palladium (Pd), and
the second adjacent layer is provided between the spacer layer and the superlattice layer.
